(19) United States
(12) Patent Application Publication
(10) Pub. No.: US 2025/0356086 A1
(43) Pub. Date: Nov. 20, 2025

(54) AUTOMATION EMBEDDED SIMULATION PLATFORM FOR RESERVOIR MODELING

(71) Applicant: Saudi Arabian Oil Company, Dhahran (SA)

(72) Inventors: Babatope Kayode, Dhahran (SA); Nayif A. Jama, Al Khobar (SA); Abdullah Kaba, Dammam (SA)

(21) Appl. No.: 18/663,784

(22) Filed: May 14, 2024

(51) Int. Cl. G06F 30/28

(52) U.S. Cl. CPC G06F 30/28

(57) ABSTRACT

Implementations provide a method that includes: accessing data comprising records of measurements from a plurality of wells of a reservoir over a period of time; removing statistical outliers from the records to generate clean records, wherein the statistical outliers represent a probability lower than a threshold; grouping, based on the clean records, the plurality of wells into a set of clusters, each cluster comprising one or more wells whose corresponding records exhibit a shared trend over at least a portion of the period of time; conducting, for each cluster, a history matching simulation using a corresponding model, wherein the corresponding model is calibrated; launching, based on results of the history matching simulation, a prediction simulation to identify at least one of an infill well and a sidetrack well within each cluster; and generating an integrated visualization for results of the prediction simulation as the prediction simulation advances.

### TECHNICAL FIELD

This disclosure generally relates to reservoir characterization and modeling in the context of geo-exploration for oil and gas.

### BACKGROUND

Reservoir modeling can be an instrumental aspect of reservoir engineering in the oil and gas industry. Reservoir modeling involves creating mathematical and computational models to simulate the behavior of subsurface reservoirs that contain hydrocarbons. A large portion of oil and gas field development may be based on three-dimensional (3D) numerical simulation results. These 3D numerical simulation results can leverage a 3D geo-model that uses core and log data obtained from wells as inputs to create a prototype of the reservoir.

### SUMMARY

In one aspect, some implementations provide a computer-implemented method comprising: accessing data comprising records of measurements obtained from a plurality of wells of a reservoir over a period of time; automatically removing statistical outliers from the records to generate clean records, wherein the statistical outliers represent a probability of occurring in the records that is below a threshold; automatically grouping, based on the clean records, the plurality of wells into a set of clusters, each cluster comprising one or more wells whose corresponding records exhibit a shared trend over at least a portion of the period of time; conducting, for each cluster, a history matching simulation using a corresponding model, wherein the corresponding model is calibrated; launching, based on results of the history matching simulation, a prediction simulation to automatically identify at least one of an infill well and a sidetrack well within each cluster; and generating an integrated visualization for results of the prediction simulation as the prediction simulation advances.

The implementations may include one or more of the following features.

The method may further comprise: in response to determining that the records have been updated, dynamically updating the integrated visualization by re-launching the prediction simulation based on the history matching simulation using the records that have been updated. Determining that the records have been updated may further comprise: scanning a database storing the records to determine whether at least one record has a time stamp that is more recent than indicated in a previous scan of the database. The corresponding model may be calibrated using a permeability (kh)-calibration based on a multi-well full-field model to compute a permeability multiplier factor to match each well's simulated derivative to a corresponding observed derivative. The method may further comprise: re-launching the history matching simulation in which the permeability multiplier factor is incorporated within a radius of the each well whose simulated derivative has been matched to the corresponding observed derivative. The method may further comprise: planning a location of a new well in the reservoir as indicated by the at least one of an infill well and a sidetrack well. The prediction simulation may identify the at least one of an infill well and a sidetrack well by searching a full simulation grid for each cluster along multiple directions of the full simulation grid. The integrated visualization may comprises a computer-generated report that assembles results from the prediction simulation. The integrated visualization comprises plots for productivity index (PI) for each well.

In another aspect, some implementations provide a computer system comprising one or more computer processors configured to perform operations of: accessing data comprising records of measurements obtained from a plurality of wells of a reservoir over a period of time; automatically removing statistical outliers from the records to generate clean records, wherein the statistical outliers represent a probability of occurring in the records that is below a threshold; automatically grouping, based on the clean records, the plurality of wells into a set of clusters, each cluster comprising one or more wells whose corresponding records exhibit a shared trend over at least a portion of the period of time; conducting, for each cluster, a history matching simulation using a corresponding model, wherein the corresponding model is calibrated; launching, based on results of the history matching simulation, a prediction simulation to automatically identify at least one of an infill well and a sidetrack well within each cluster; and generating an integrated visualization for results of the prediction simulation as the prediction simulation advances.

The implementations may include one or more of the following features.

The operations may further comprise: in response to determining that the records have been updated, dynamically updating the integrated visualization by re-launching the prediction simulation based on the history matching simulation using the records that have been updated. Determining that the records have been updated may further comprise: scanning a database storing the records to determine whether at least one record has a time stamp that is more recent than indicated in a previous scan of the database. The corresponding model may be calibrated using a permeability (kh)-calibration based on a multi-well full-field model to compute a permeability multiplier factor to match each well's simulated derivative to a corresponding observed derivative. The operations may further comprise: re-launching the history matching simulation in which the permeability multiplier factor is incorporated within a radius of the each well whose simulated derivative has been matched to the corresponding observed derivative. The operations may further comprise: planning a location of a new well in the reservoir as indicated by the at least one of an infill well and a sidetrack well. The prediction simulation may identify the at least one of an infill well and a sidetrack well by searching a full simulation grid for each cluster along multiple directions of the full simulation grid. The integrated visualization may comprises a computer-generated report that assembles results from the prediction simulation. The integrated visualization comprises plots for productivity index (PI) for each well.

In yet another aspect, some implementations provide one or more computer storage devices comprising software instructions which, when executed by one or more computer processors, cause the one or more computer processors to perform operations of: accessing data comprising records of measurements obtained from a plurality of wells of a reservoir over a period of time; automatically removing statistical outliers from the records to generate clean records, wherein the statistical outliers represent a probability of occurring in the records that is below a threshold; automatically grouping, based on the clean records, the plurality of wells into a set of clusters, each cluster comprising one or more wells whose corresponding records exhibit a shared trend over at least a portion of the period of time; conducting, for each cluster, a history matching simulation using a corresponding model, wherein the corresponding model is calibrated; launching, based on results of the history matching simulation, a prediction simulation to automatically identify at least one of an infill well and a sidetrack well within each cluster; and generating an integrated visualization for results of the prediction simulation as the prediction simulation advances.

The implementations may include one or more of the following features.

The operations may further comprise: in response to determining that the records have been updated, dynamically updating the integrated visualization by re-launching the prediction simulation based on the history matching simulation using the records that have been updated. Determining that the records have been updated may further comprise: scanning a database storing the records to determine whether at least one record has a time stamp that is more recent than indicated in a previous scan of the database. The corresponding model may be calibrated using a permeability (kh)-calibration based on a multi-well full-field model to compute a permeability multiplier factor to match each well's simulated derivative to a corresponding observed derivative. The operations may further comprise: re-launching the history matching simulation in which the permeability multiplier factor is incorporated within a radius of the each well whose simulated derivative has been matched to the corresponding observed derivative. The operations may further comprise: planning a location of a new well in the reservoir as indicated by the at least one of an infill well and a sidetrack well. The prediction simulation may identify the at least one of an infill well and a sidetrack well by searching a full simulation grid for each cluster along multiple directions of the full simulation grid. The integrated visualization may comprises a computer-generated report that assembles results from the prediction simulation. The integrated visualization comprises plots for productivity index (PI) for each well.

Implementations according to the present disclosure may be realized in computer implemented methods, hardware computing systems, and tangible computer readable media. For example, a system of one or more computers can be configured to perform particular actions by virtue of having software, firmware, hardware, or a combination of them installed on the system that in operation causes or cause the system to perform the actions. One or more computer programs can be configured to perform particular actions by virtue of including instructions that, when executed by data processing apparatus, cause the apparatus to perform the actions.

The details of one or more implementations of the subject matter of this specification are set forth in the description, the claims, and the accompanying drawings. Other features, aspects, and advantages of the subject matter will become apparent from the description, the claims, and the accompanying drawings.

### DESCRIPTION OF DRAWINGS

FIG. 1 is a diagram illustrating examples of dynamic modeling tasks automatically handled on a simulator platform according to an implementation of the present disclosure.

FIG. 2 is another diagram illustrating components and workflow on the platform of FIG. 1 according to an implementation of the present disclosure.

FIGS. 3A and 3B show examples of data quality check prior to history matching according to an implementation of the present disclosure.

FIG. 4 shows an example of a global set of historical datum pressures of all wells in an example reservoir according to an implementation of the present disclosure.

FIG. 5A shows four pressure clusters derived from the global dataset of FIG. 4 according to an implementation of the present disclosure.

FIG. 5B shows a map indicating each group of wells of FIG. 5A within the same pressure cluster and enclosed by a boundary polygon according to an implementation of the present disclosure.

FIG. 6A illustrates a map loaded with polygons delineating groups of wells having similar historical pressure trends according to an implementation of the present disclosure.

FIG. 6B provides a three-dimensional (3D) rendition of the polygons of FIG. 6A into a 3D region number array according to an implementation of the present disclosure.

FIG. 7 shows an example of a diagnostic derivative plot used for model calibration according to an implementation of the present disclosure.

FIG. 8 shows an example of integrated visualization according to an implementation of the present disclosure.

FIG. 9 shows an example of integrated visualization where all Modular Formation Dynamics Tester (MDT) pressure match the observed data in one view according to an implementation of the present disclosure.

FIG. 10 shows an example of a production index (PI) calibration chart generated by platforms according to an implementation of the present disclosure.

FIG. 11 illustrates a sidetrack well actually drilled, which has been automatically created by a disclosed simulator platform during the course of a simulation run according to an implementation of the present disclosure.

FIGS. 12A and 12B illustrate additional details of applying the side-track from the examples of FIG. 11 according to an implementation of the present disclosure.

FIG. 13 illustrates an example of a computer-implemented method according to an implementation of the present disclosure.

FIG. 14 is a block diagram illustrating an example of hydrocarbon production operations that include field operations and computational operations, according to an implementation of the present disclosure.

FIG. 15 is a block diagram illustrating an example of a computer system used to provide computational functionalities associated with described algorithms, methods, functions, processes, flows, and procedures, according to an implementation of the present disclosure.

Like reference numbers and designations in the various drawings indicate like elements.

### DETAILED DESCRIPTION

The disclosed technology is directed to an integrated software system for model-based reservoir performance characterization. Some implementations can provide a software platform that performs the full complement of reservoir modeling in automated fashion including pre-processing for quality control, history matching (HM), as well as permeability (kh)-calibration and full-field history run driven by the permeability calibration. Pre-processing can use data analytics and machine learning techniques to read, e.g., the input pressure dataset into memory, remove statistical outliers from the dataset, and create a clean dataset for HM statistics. During history matching, the integrated software system can delineate the reservoir into regions having similar time-lapsed pressure trend for permeability modification in each region using 3D modelling for the identified region. The integrated software system applies artificial intelligence to perform kh-calibration using a multi-well full-field model approach for each of the hundreds of wells in each cluster to achieve the full-field history-match. At the end of the full-field history run, the integrated software can compute the permeability multiplier factor for matching each test-well's simulated derivative to its observed data derivative. Armed with the permeability correction factors for each tested-well, the integrated software system automatically resumes a new simulation run in which it has incorporated the calculated multiplier within, for example, a 1 km radius of the applicable wells. The integrated software system also includes an integrated visualization interface which the simulator creates for every simulation run and updates the plots as the simulation advances (e.g., monthly, annually, or each time-step) for instant visualization of plots of all relevant simulation results. The integrated software system further incorporates calibration of productivity index (PI) by obtaining the simulated PI of the wells and calculating the multiplier factor, if needed, between the actual PI and the simulated PI. The integrated software system can further search the entire simulation grid of the reservoir at temporal intervals (e.g., annually) to identify the best spots to drill infill wells. The integrated software system can additionally generate a report of the predicted reservoir characteristics (e.g., PI) after simulation. The integrated software system allows live model update.

For additional context, the industry simulator developers have focused on advancements in handling of larger number of active grids, and development of more robust flow physics to describe e.g., fractures. In contrast, the disclosed technology operates by embedding automation, machine learning and data analytics to create an intelligent simulation platform which not only simulates flow physics, but also performs additional pre- and post-simulation tasks to seamlessly provide an integrated solution. For clarity, the integrated simulation platform is not where users can perform their tasks, but rather an automation driven platform that bridges tasks hitherto performed by users. Significantly, the integrated simulation platform can optimize the project timeline and improve model robustness during integrated reservoir studies by leveraging process automation through artificial intelligence/machine learning (AI/ML) and data analytics, much like AI-driven graphics generator using otherwise disparate data sources based on user prompts. Indeed, the disclosed technology changes the perspective of computer-implemented reservoir modeling by seamlessly integrating quality, speed and process so that the user can reap the benefits of such change of perspective, just like an operator providing prompts to an AI-driven generator and to receive generated text or graphics.

The disclosed technology can incorporate a full-field simulator equipped with artificial intelligence for automatic multi-well kh-conditioning. Here, kh refers to the permeability-thickness product, in md-ft, where h is thickness in feet, and k is permeability in the horizontal direction in milli Darcy (md). Permeability-thickness (kh) conditioning is the process of modifying a geological model's permeability field so that the model's kh around certain wells that have historical well-test data can become similar to the well-test derived kh of the wells. By way of examples, the disclosed simulator automatically determines the middle time region (MTR) section of each well's pressure derivative plot based on the measured well-test data and calculates the permeability multiplier factor, which can be used to condition the model permeability according to the well-test permeability to ensure similar kh between the observed MTR derivative and simulated MTR derivative by modifying the geological model permeability around each well in the reservoir that has well-test event. Similarity of kh can be implied when the MTR of the derivative of historical and simulated well-test pressures transient have similar magnitude. Accordingly, the implementations can interpret the kh measurements from actual well-test data and then compare the derived kh measurements with the kh values predicted by the geological modeling process at the location of the wells having well-test records. As a result, the implementations can obtain a permeability correction factor, which can be used to condition the model permeability to the well-test permeability.

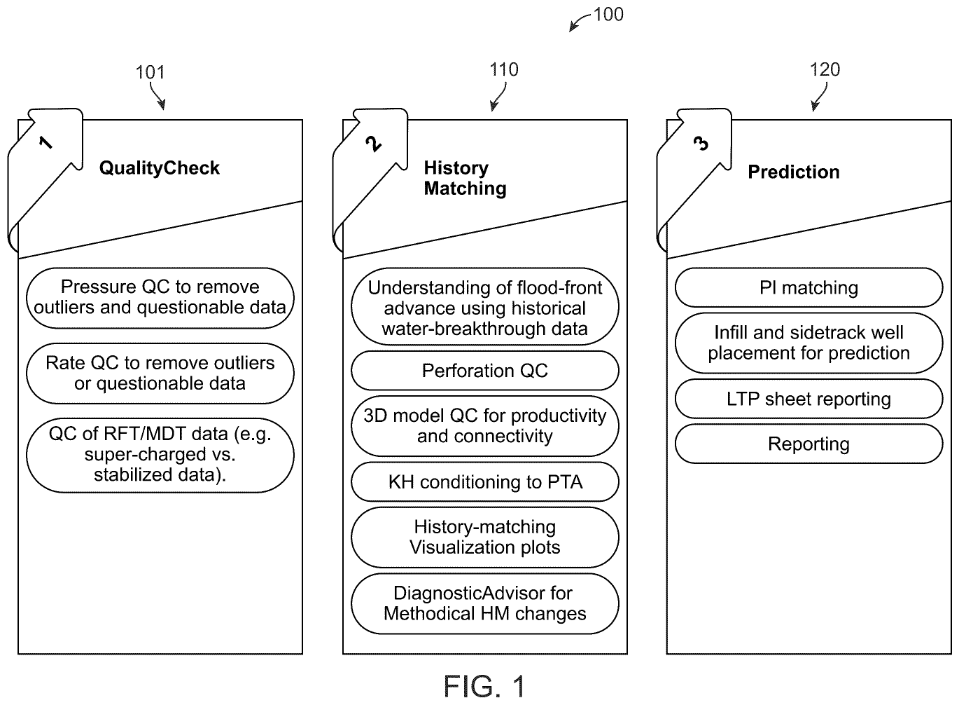

Significantly, kh conditioning improves the prediction quality of infill wells. In large reservoirs with test data from hundreds of wells, thorough kh-conditioning to well test data can be technically challenging in terms of computation. By virtue of the permeability correction approach presented in the present disclosure, implementations can more realistically calibrate the full field, rather than being limited to the locations of the cored wells in the field. In other words, implementations can leverage the kh multipliers at wells that have well test events to extrapolate positions elsewhere in the field to provide a more realistic rendering of the full field using the new geological model. The salient features are similar to improved computerized animation. Moreover, the data-driven computational aspects entail voluminous data obtained from a vast geophysical exploration site. Indeed, the implementations are not limited by, for example, an upper bound of wells at the geophysical site. In fact, the technical improvements scale up with the number of wells at the geophysical exploration site. This scale-up aspect is another hallmark of the technical improvement directed to the underlying computerized technology. More details are provided below, in association with FIGS. 1-15.

### Glossary of Terms

Core Data can include core samples taken out of actual reservoir formations under in-situ conditions during drilling phase of the wells, which can provide valuable data on reservoirs and fluids. Core data may only be collected in a few wells depending upon the objectives. Core data samples can be transferred to a laboratory for detailed analyses. When available, core data can provide more reliable reservoir fluid properties than petrophysical log data. In some cases, core data can be used to adjust or calibrate log data. This may be done because core data can be considered more reliable than the log data. In cases in which core data is not available, techniques can rely on petrophysical log data. If core data in offset wells is available, then the core data can also be used for enhancing reservoir descriptions.

Geology and Geophysics Data can be collected from the field seismic survey. Collected seismic field data can be input into the workflow where the data can be analyzed and interpreted to derive geological structures, rock typing, and reservoir features (including fractures, faults, and unconformity) of the reservoir. As the seismic data has the capability of capturing only large features in the field or the reservoir, localized geological features may be missed, such as fractures, faults, and unconformity. Based on the shape of the reservoirs, structural maps (for example, contour maps) can be generated by using depth scales. By using contour maps along with seismic interpretation, rock typing can be determined. Reservoir structures as interpreted from seismic data can be incorporated in numerical models if structural contour maps are available from seismic data.

An Operational Platform can serve as a computer-aided enabler in performing specific operations on a sector model that is regarded as an operational platform. Such a platform can execute requests for visualization of, and computational operations on, uploaded models. The operational platform can also display input parameters and field data, compute model outputs, and compare model outputs to field data. The operational platform can also have the capability of simplifying well trajectories, production data, and injection data to reduce the computational burden. Manipulation of grids, including upscaling and refining as needed, can also be performed on sector models.

Petrophysics can refer to reservoir properties (for example, permeability, porosity, saturations, and pay thickness) originating from petrophysical log data to build static geological models. Petrophysical logs can be built during the drilling phase of the well. Logging tools can be run in-hole. Wellbore, rock, and fluid information can be collected, which can later be processed and analyzed to estimate detailed reservoir properties such as permeability, porosity, saturations, and thickness. Petrophysical logs can provide the resolution needed to pick up localized features in the well or in the vicinity of the well. Logs can be the primary sources of most important and reliable data, providing a detailed description of the rock, fluid, and well. This information can be input to static geological models. In case a given subject well does not have petrophysical information, modelers can turn to other offset wells for petrophysical data for building the models.

PVT Data includes data for pressure, volume, and temperature (PVT), which serve as reservoir fluid properties. A PVT analysis can include the process of determining the fluid behaviors and properties of oil, water, and gas samples from a reference well. Fluid samples for PVT analyses can be collected from a well during a drilling phase or a production phase of the well. The PVT data can also help in defining the phase behavior of reservoir fluids. Formation volume factors, viscosity, gas gravity, gas-oil ratio, and water salinity data can be used in a dynamic reservoir model. The PVT data use can be based on the number of phases (for example, two or three phases) in the reservoir.

A Reference Point is a depth at which all gauges are set to measure pressure data. The pressure at the reference point (for example, the gauge depth of the pressure measurement) can be required to initialize and simulate the pressure transient data in the transient model. Models can calculate simulated pressures at the reference point.

Relative Permeability refers to a concept used to enforce a preferential level of flow capacity due to the presence of multiple fluids at a given location in the reservoir. Relative Permeability can depend upon pore geometry, wettability, fluid distribution, and fluid saturation history. Relative permeability measurements can be conducted on core samples in a laboratory. Relative permeability measurements can be both time-consuming and expensive to produce.

As an example, in a single-phase fluid system, such as a dry gas or an under-saturated oil reservoir, the effective permeability of flow of the mobile fluid through the reservoir may vary a little during production because the fluid saturations do not change much. However, when more than one phase is mobile, the effective permeability to each mobile phase can change as the saturations of the fluids change in the reservoir. In the multiphase flow of fluids through porous media, the relative permeability of a phase can be a dimensionless measure of the effective permeability of that phase. The relative permeability can be represented as the ratio of the effective permeability of that phase to the absolute permeability. Relative permeability can be required for the calculation of permeability in each phase.

Reservoir Initial Conditions refer to the conditions when a well was drilled or before the well was subjected to any production or injection. The pressure and temperature data collected at that time is called the initial pressure and temperature of the reservoir. In addition, depths of the oil-water contact (OWC) and the gas-oil contact (GOC) need to be captured as well. These initial conditions can be utilized to build a hydro-dynamically balanced version of the transient model before the production and injection occur.

Well Control, Pressure-Transient Data, and Production Rates, when used in executing transient modeling, help to define well data in the well. In well control parameters, well history with reference to transient time can be defined. The production or injection history in different phases (for example, oil, water, or gas) separately can also be defined. The production or injection history can be required to match the pressure-transient data. Information for all flow, buildup, and fall-off periods of the wells can be defined in the data. Transient data of the measured pressures and production rates can be input into the transient model so that the information can be matched with the corresponding model predictions during simulation runs. The transient data of the measured pressures and the production rates can also help to accommodate any constraints. The constraints can be used, for example, to assure that well production rates and pressures do not go below or exceed certain limits during production or the shut-in phase. Constraints can be optional.

A Pressure Transient Analysis (PTA) well-test, also known as pressure transient testing or well testing, is a method used in reservoir engineering to evaluate the properties of a reservoir and assess the performance of a well. PTA involves measuring pressure changes in the wellbore or reservoir over time in response to controlled variations in production or injection rates. PTA provides valuable information about reservoir characteristics, including permeability, reservoir pressure, skin, and other parameters.

Well Trajectory and Completion Data includes a well trajectory defining the well path along which the well is drilled in a reservoir. In the past, wells were drilled vertically into the ground, and the well trajectory was essentially a straight, vertical line. In current operations, wells can be drilled so that the well trajectory can be horizontal, deviated, and curved. A numerical model can be used to capture the actual well trajectory. However, complex well trajectories may be numerically expensive for generating simulated pressures.

Well Completion is the process of making a well hydraulically connected to the intersecting reservoir to facilitate production or injection. Well completion principally involves preparing the bottom of a hole to predetermined specifications and running in the production tubing. Well completion is associated with downhole tools, including perforating and stimulating as required. Types of perforation can be based on the type of completion, for example, open-hole or cased-hole completions.

A Geological (Static) Model is a geological model that can be built using all static data (including geology, geophysics, petrophysical, fluid contacts, and core data) that provide characteristics of reservoir properties. The geological model also includes drilled wells with their trajectories. The geological model is the first step in modeling any field, and is usually built for the full field before being converted to a full-field dynamic simulation model. The geological model usually does not include dynamic data.

Infinite Acting Radial Flow (IARF) regime, refers to, in the context of reservoirs, fluid flow from the reservoir toward a wellbore where the reservoir is sufficiently large or the flow rates are sufficiently slow that the effects of the reservoir's outer boundary on the well's pressure transient are not yet felt. In other words, the reservoir is behaving as if it extends infinitely in all directions.

Modular Formation Dynamics Tester (MDT) is a downhole tool used in the oil and gas industry to measure formation pressure, collect fluid samples, and evaluate reservoir properties during wireline logging or testing operations. MDT data, particularly pressure measurements, can be used for pressure transient analysis to evaluate reservoir performance, assess reservoir drive mechanisms, and estimate reservoir properties such as permeability and reservoir pressure.

Repeat Formation Tester (RFT) is a downhole tool used in the oil and gas industry to measure formation pressure, collect fluid samples, and evaluate reservoir properties during wireline logging or testing operations. The RFT tool is equipped with a sampling module that allows it to collect fluid samples from the reservoir. RFT data, particularly pressure measurements, can be used for pressure transient analysis to evaluate reservoir performance, assess reservoir drive mechanisms, and estimate reservoir properties such as permeability and reservoir pressure. MDT tools and RFT tools differ in their deployment methods, sampling capabilities, and application scenarios.

Stock tank oil initially in place (“STOIIP”) is a term used in the oil and gas industry to refer to the total estimated amount of crude oil present in a reservoir before any extraction or production activities have taken place. STOIIP represents the volume of oil that theoretically exists in the reservoir under initial conditions, typically measured at reservoir pressure and temperature. The calculation of STOIIP is a fundamental step in reservoir evaluation and resource estimation, providing crucial information for assessing the economic viability and potential productivity of an oil reservoir. The estimation of STOIIP involves various geological and engineering analyses for reservoir mapping, reservoir rock properties, fluid properties, and reservoir volume calculation. STOIIP calculations can provide the foundation for reserve estimation, production planning, and economic analysis in the oil and gas industry, thereby aiding reservoir development and field management.

PLT typically refers to production log tool/technique (PLT), which includes interpretation techniques aimed at matching measured data from PLT surveys with model predictions or expectations. PLT matches provide a valuable tool for production surveillance and optimization in the oil and gas industry. For example, PLT matches can provide valuable insights into the performance of individual wells and the overall reservoir behavior, helping operators maximize production and recovery while minimizing costs and risks.

PNL refers to pulsed neutron log/logging, which well logging technique used to measure formation porosity and lithology, determine fluid saturation, identify hydrocarbon zones, and assess reservoir properties. In pulsed neutron logging, a neutron generator emits bursts of high-energy neutrons into the formation surrounding the wellbore. These neutrons interact with the formation, causing various reactions, including neutron capture and scattering. Detectors in the logging tool measure the resulting gamma rays, which provide information about the formation's composition, porosity, and fluid content. PNL read out can provide direct measurements of formation properties and thus assist in assessing reservoir quality and hydrocarbon potential.

FIG. 1 is a diagram 100 illustrating examples of dynamic modeling tasks automatically handled on a simulator platform according to an implementation of the present disclosure. As illustrated in FIG. 1, the platform incorporates quality check module 101, history matching module 110, and prediction module 120.

The simulator platform leverages dynamic modeling to simulate a static model and compare the simulator outputs to applicable historical data during a process called history-matching. The history-matched model is then used to define infill or side-track well locations during a process termed prediction. The outcomes of the history-matching process and a prediction process may be included in internal reports for economic evaluation, or for submission to regulatory agencies such as SEC disclosure. Example results from the prediction process can include STOIIP results, recovery factor, well-types (producer, injector) and well count, production/injection rate profiles, pressure.

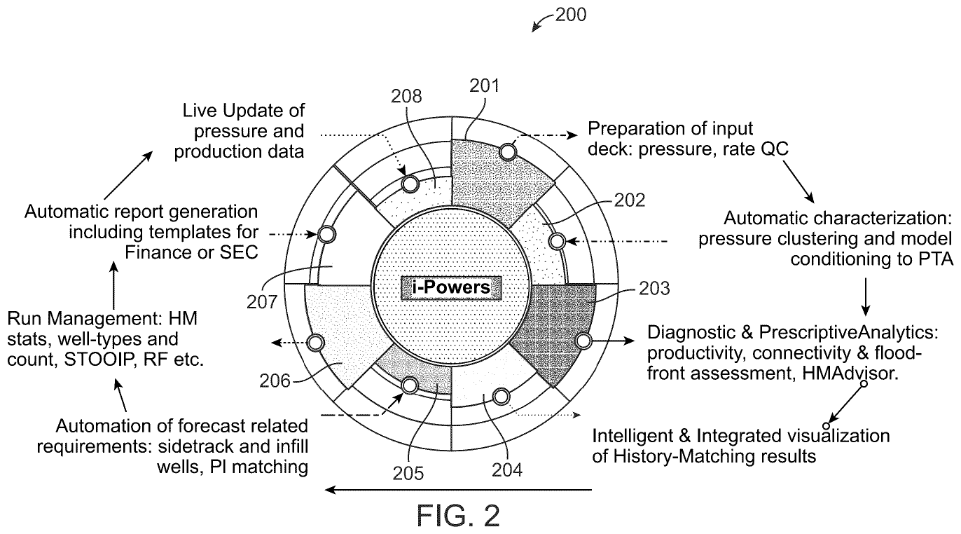

Referring to FIG. 2, FIG. 2 is another diagram 200 illustrates components and workflow on the platform of FIG. 1 according to an implementation of the present disclosure. Diagram 200 includes arc 201 (preparation of input deck), arc 202 (automatic characterization), arc 203 (diagnostic and prescriptive analytics), arc 204 (visualization of history-matched results), arc 205 (automation of forecast related requirements), arc 206 (simulation run management), arc 207 (report generation), and arc 208 (live update)

Returning to FIG. 1, quality check module 101 can handle data inconsistencies after importing data and before further processing such as history matching and model-based predictions. For example, quality check module 101 can conduct quality control of pressure data to remove outliers and questionable input data. Quality check module 101 can also conduct quality control of rate (e.g., production rate) data to remove outliers and questionable data in the records. Quality check module 101 can additionally conduct quality control of other types of data, e.g., MDT data, and RFT data, to remove outliers and questionable data in the records. Quality check module 101 of FIG. 1 is reflected in arc 202 of FIG. 2 where the workflow attends to preparation of input deck, which includes quality check of, for example, pressure and rate data.

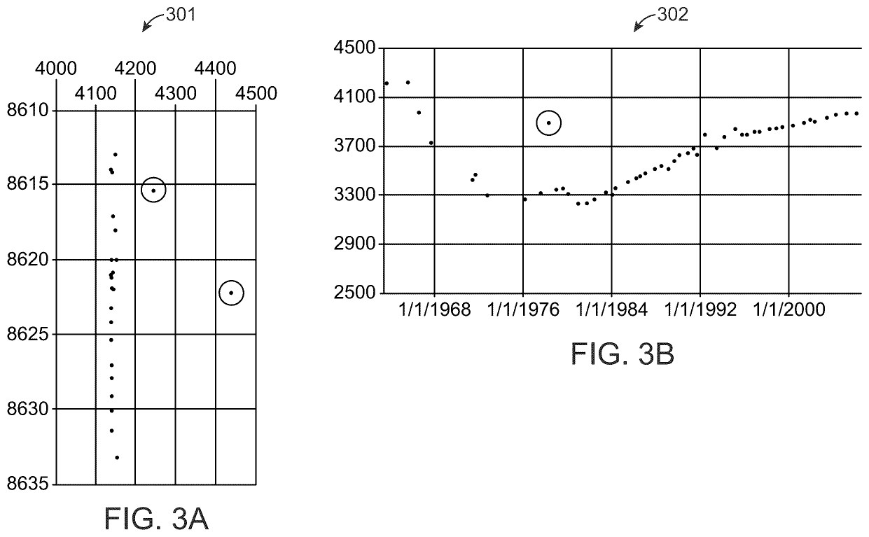

Further referring to FIGS. 3A and 3B, FIGS. 3A and 3B show examples, 301 and 302, respectively of data quality check prior to history matching according to an implementation of the present disclosure. In FIG. 3A, example 301 of the pressure versus depth data (known as MDT/RFT pressure data) is shown, with two outliers identified in circles. Similarly, in the pressure versus date data shown in example 302 of FIG. 3B, an outlier is identified using a circle. For context, outliers can be a significant distraction that hinders automatic history-matching. For example, outliers can result in large values of mis-matched coefficient, e.g., root mean square error, which could disorient the simulator into continued requests for history-match, and hence continue to try indefinitely without a successful match. Here, an outlier refers to a statistic outlier that differs from neighboring samples by more than a statistically significantly amount (e.g., two standard deviations). Because a reservoir simulator is coded based on flow physics, the simulator would not respond to non-physics-based data. As such, if such outliers are not cleaned from the historical dataset, the outlier would show as a misfit error in the history matching statistics. The level of misfit can be significant for a project involving several hundreds of wells. Here, the traditional practice of manually cleaning such datasets for every well is time consuming and prone to errors. The disclosed simulator platform is installed with data analytics and machine learning techniques, which can be invoked to read the input pressure dataset into the simulator's memory, clean the dataset to create clean dataset for history matching (HM) and for reporting HM statistics. Some implementations may incorporate a similarity test by applying a multivariable linear regression to input data that include data records collected at regular time intervals (for example, monthly intervals), and eliminating data records having less than, for example, 10% probability of occurrence within each time interval.

After applying the clean input data to a static model, the history matching module 110 of FIG. 1 can compare the simulator outputs to applicable historical data. As illustrated in FIG. 1, history matching module 110 may include understanding of flood-front advance using historical water-breakthrough data, perforation quality control (QC), 3D model QC for productivity and connectivity, kh conditioning to PTA, history matching visualization plots, and diagnostic advisor for methodical HM changes. As illustrated in FIG. 2, the disclosed simulator platform can perform automatic characterization including pressure clustering and model conditioning to PTA (arc 202).

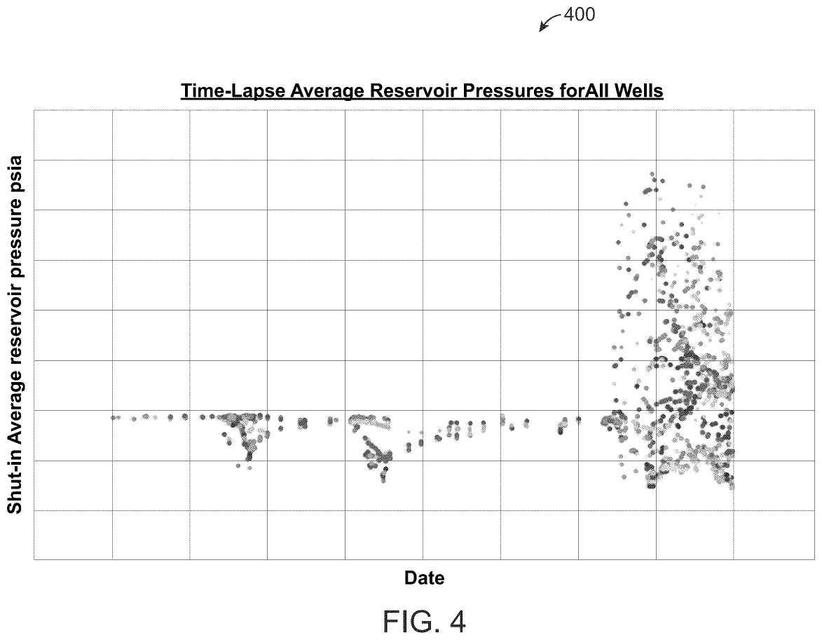

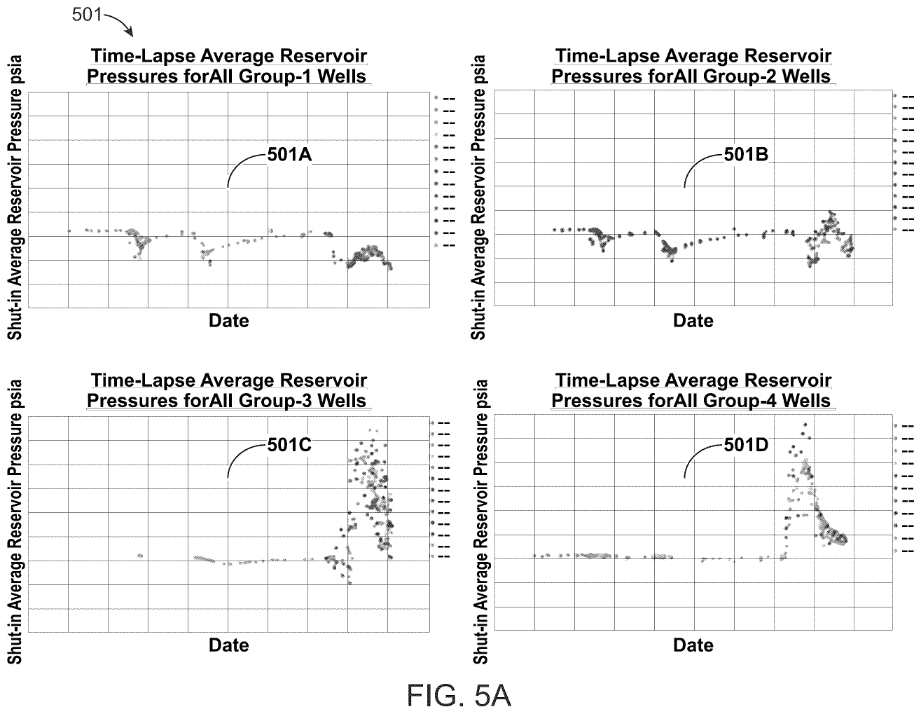

Here, the disclosed simulator platform may delineate the reservoir model into regions having similar time-lapse pressure trend. The resulting model regions can then be used for sub-global permeability modifications during history-matching. For example, FIG. 4 shows an example 400 of a global set of the historical datum pressures of all wells in an example reservoir according to an implementation of the present disclosure.

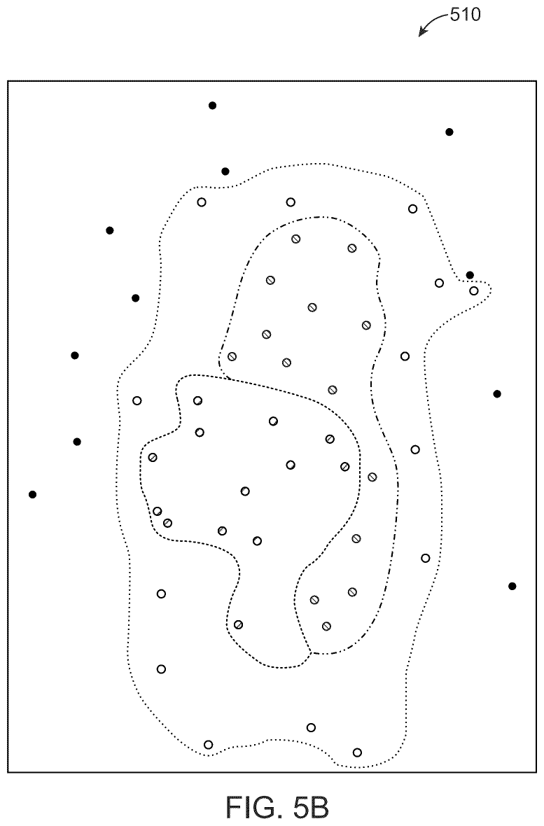

Based on the global set of pressure data from FIG. 4, FIG. 5A shows example 501 that includes four pressure clusters derived from the global dataset of FIG. 4 according to an implementation of the present disclosure. Each cluster includes locations of wells where the pressure data records revealed similarities (e.g., a similar trend over time). As illustrated in FIG. 5A, four (4) different pressure clusters, namely, clusters 501A, 501B, 501C, and 501D are identified in example 501. Each cluster contains several wells whose pressure data are of similar magnitude and trend, and are dissimilar to the magnitude and trend of the other three clusters.

FIG. 5B shows a map 510 indicating each group of wells of FIG. 5A within the same pressure cluster and enclosed by a boundary polygon according to an implementation of the present disclosure. The polygons of FIG. 5B may then be passed to a 3D modeling tool to be converted into a 3D array property. The 3D array containing a unique region number for all grid-blocks within each closed polygon may then exported into a simulator to be used for making regional permeability updates. During the pressure clustering process, the spatial locations of the resulting well groups may be plotted in a 3D modeling tool for generating a polygon around each group of wells and converting the polygon regions into a 3D grid array.

The disclosed simulator platform can be programmed to conduct clustering using pattern recognition, provide automatic creation of boundary polygons around identified well groups, and apply an automatic re-shaping algorithm that translates a two-dimensional (2D) polygon into a 3D array containing a unique region number within each closed polygon. During initialization, the simulator platform may create a simulation array for the identified pressure regions so that history-matching modifications can then be applied on these regions during runtime. Here, a simulation array refers to a grid/matrix of numerical values, for example, stored in a digitized memory. The clustering may be performed by a pattern recognition algorithm.

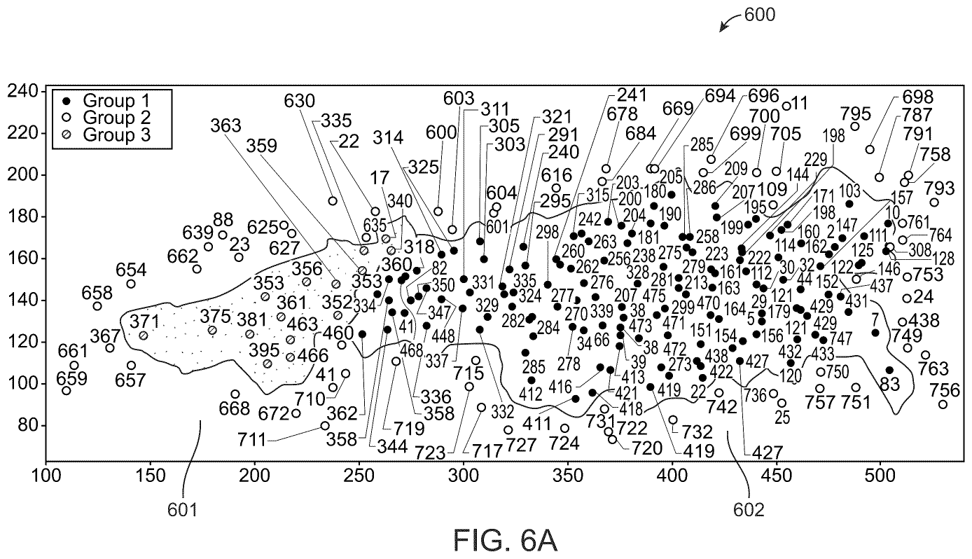

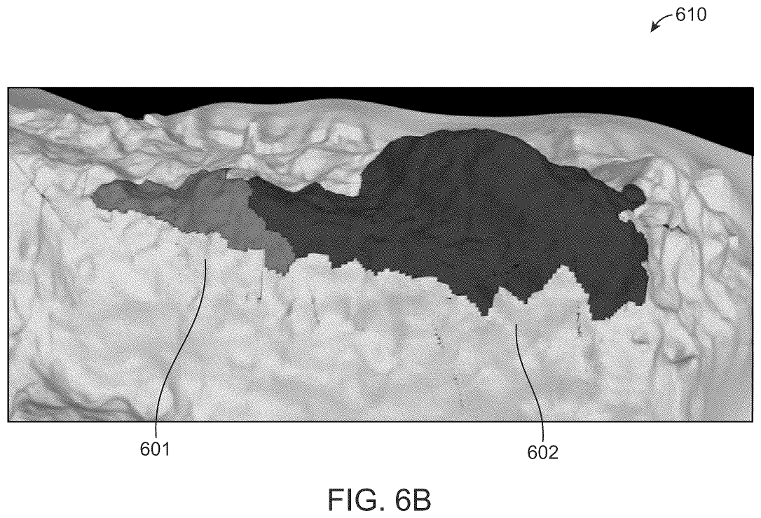

FIG. 6A illustrates a map 600 loaded with polygons delineating two groups of wells (namely, group 601 and group 602) having similar historical pressure trends according to an implementation of the present disclosure. The resulting map may then be extended (e.g., reshaped) into 3D by duplicating the pressure group in each grid of the map to all the column of grids below.

FIG. 6B provides 3D rendition 610 of the polygons of FIG. 6A into a 3D region number array according to an implementation of the present disclosure. Both groups 601 and 602 are represented. In some implementations, the simulator pre-script can apply a Python machine learning (ML) Voronoi Algorithm to implement a closed polygon around all wells within each pressure cluster. As illustrated in FIG. 2, the simulator platform can provide diagnostic & prescriptive analytics on productivity, connectivity, flood-front assessment, and HM advisor (arc 203), as well as intelligent and integrated visualization of history-matching results (arc 204).

The disclosed simulator platform may condition the geological model's kh to the kh interpreted from well-testing. The kh conditioning process may include the simulation of a well's historical test-rate so that the resulting simulated pressure transient can be compared with the actual measured pressure transient using, for example, the diagnostic derivative plot approach. The permeability around the tested well may then be updated until the simulated and observed pressure derivative are similar.

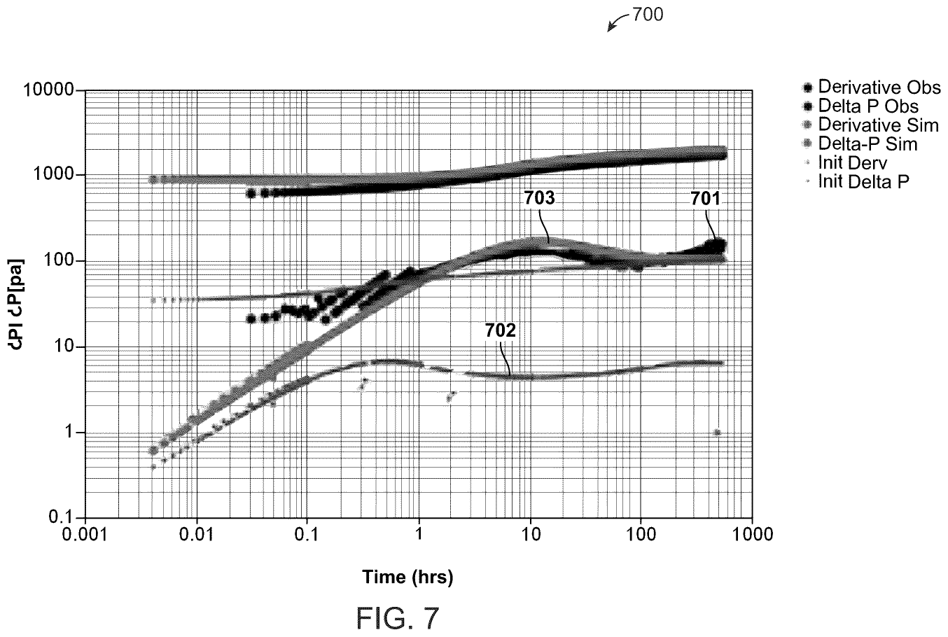

FIG. 7 shows an example of using diagnostic derivative plots for model calibration according to some implementations of the present disclosure. As illustrated in graph 700 of FIG. 7, plot 701 is the diagnostic derivative plot for the observed pressure transient, and plot 702 is the diagnostic derivative of the tested well's simulated pressure transient at its location in the geological model. After permeability modification, plot 703 is the diagnostic derivative of the well. As can be seen, plot 703 is closer to plot 701 than plot 702, especially in the mid-time region.

Specifically, the disclosed simulator platform is encoded with artificial intelligence to perform kh-calibration using a multi-well full-field model approach. Instead of the traditional approach using a single-well sector model for each of 100's of wells, the disclosed simulator platform cab run the full-field history-match and conduct kh-conditioning at the relevant test dates of tested wells. At the end of the full-field history run, the disclosed simulator platform can launch a post job script to compute the permeability multiplier factor necessary to match each test-well's simulated derivative to its observed data derivative. Armed with the permeability correction factors for each tested-well, the disclosed simulator platform can automatically resume a new simulation run in which the calculated multiplier is incorporated within 1 km radius of the applicable wells.

Another hallmark characteristic of the disclosed simulator platform is automatic creation of advanced visualization templates. For context, today's simulators only conduct the simulation run, and the user would need to load the simulation results into an external application for creating result visualization. In projects covering several hundreds of wells, visualization of relevant results including production matches, datum pressure matches, PLT matches, PNL matches, MDT matches can be laborious and time consuming, making the visualization cumbersome for the engineer to thoroughly review the results of a completed simulation run.

In comparison, the disclosed simulator platform is programmed to provide an integrated visualization interface through which the simulator can create a visualization output (e.g., plots), for every simulation run, and update the visualization output as the simulation progresses (monthly, yearly, or every time-step). In this situation, the engineer may operate in an auto-pilot mode to let the simulator platform provide visualization of the progressive results of the ongoing simulation run without having to individually create any one of the visualization output or operate an external application to load the simulation results for display. The simulator platform can automatically redirect the simulation results to the relevant visualization output and refresh the output in the event of updated simulation results (or new simulation runs).

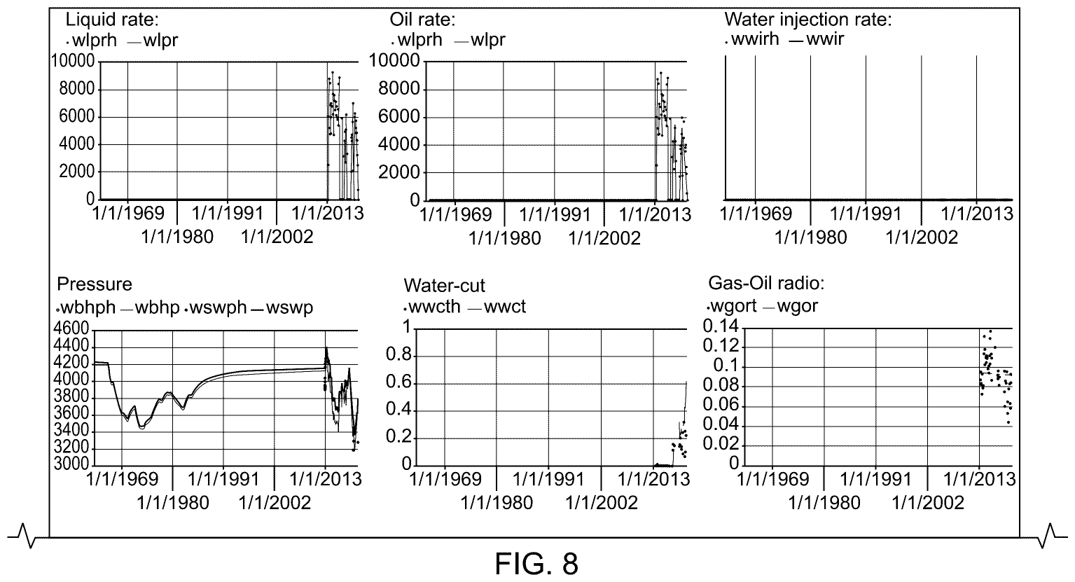

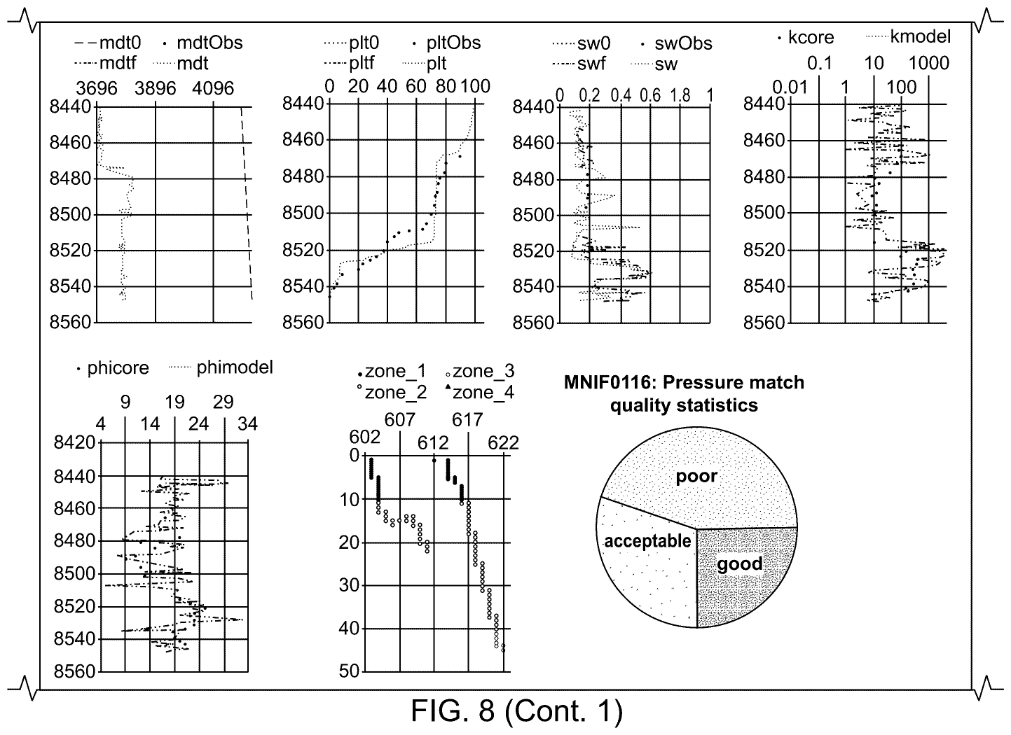

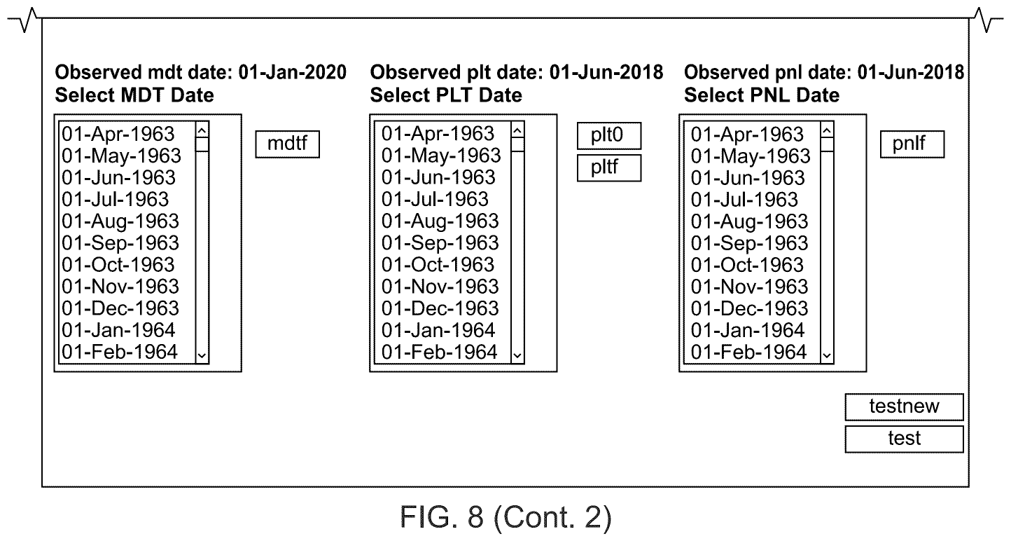

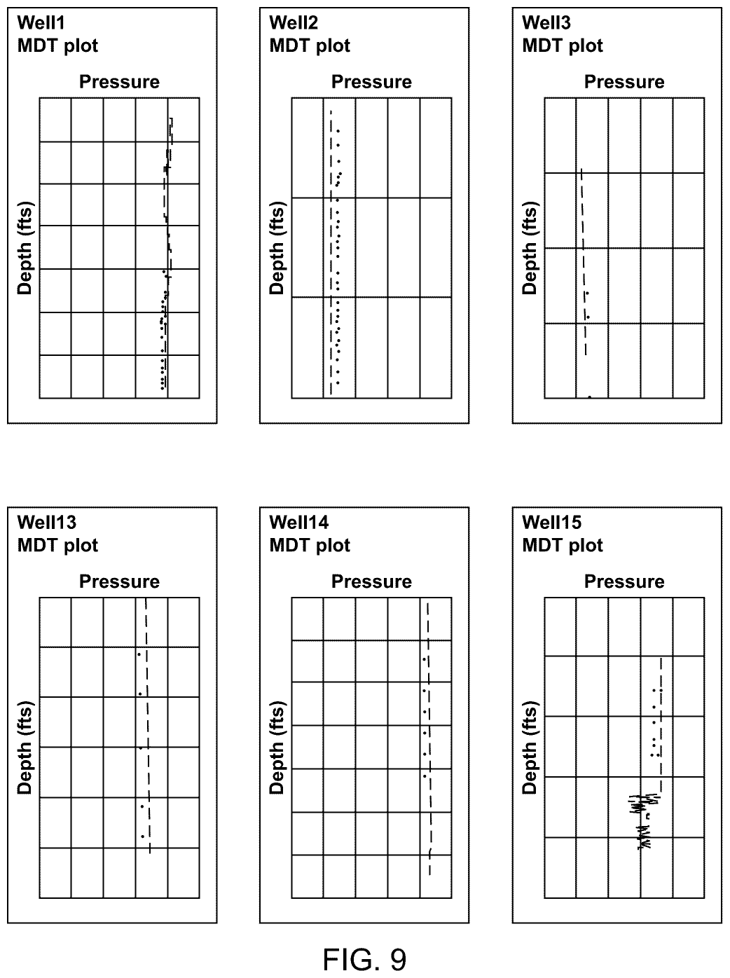

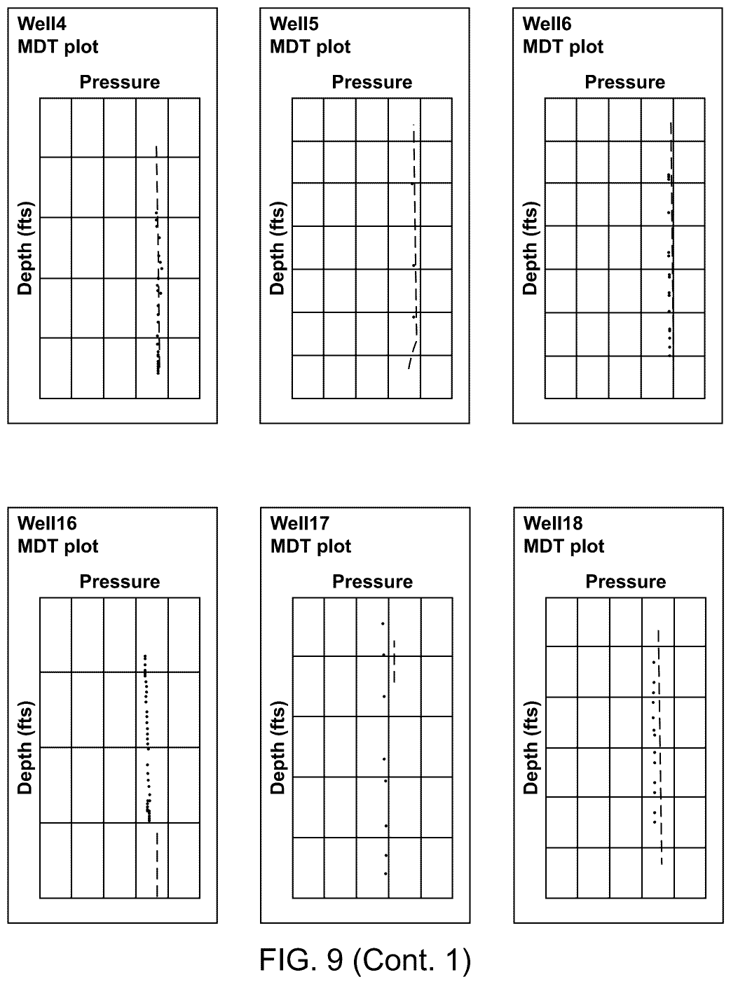

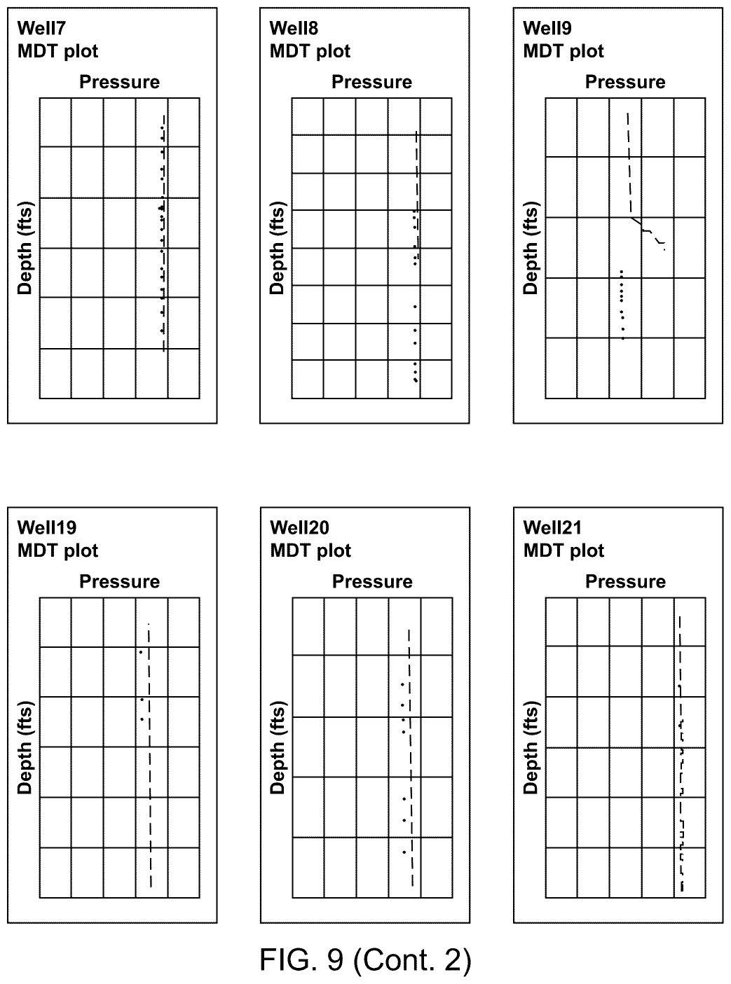

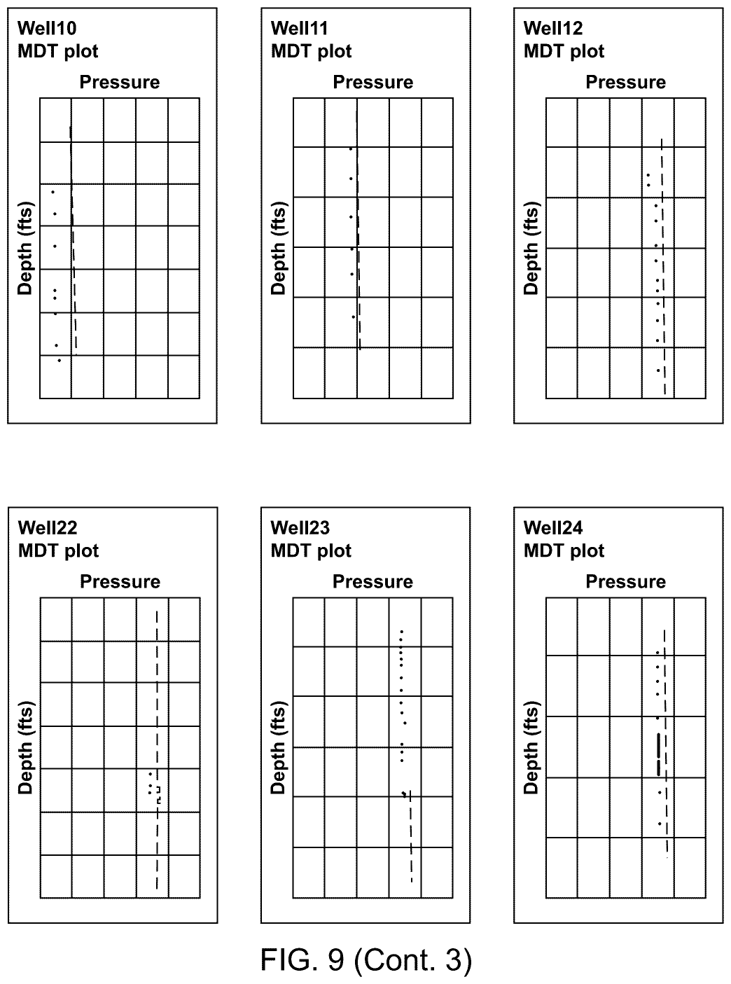

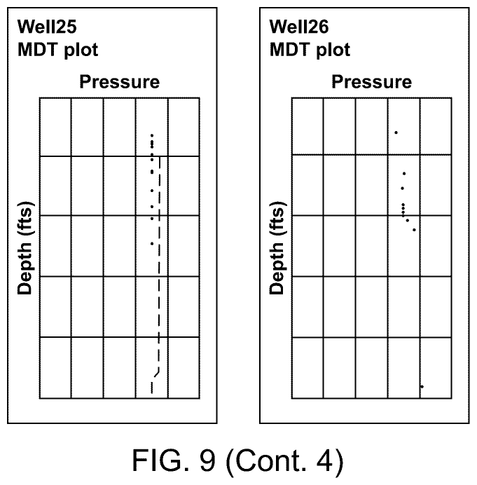

Indeed, the disclosed simulator platform also fills a knowledge gap when less experienced engineers may not know what type of simulation results to visualize or how to extract those results. The disclosed simulator platform automatically and by default presents visualization plots of all relevant simulation results, thereby facilitating user review of the simulation case and subsequent decision on new case to be submitted. Some implementations provide integrated visualization that combines, for example, production, production ratios (e.g., water-cut, gas-oil-ratio (GOR)), historical datum pressures, MDT, PNL, PLT, perforations zones, porosity and permeability into a single visualization interface for each well, as further explained below with reference to each subpanel in FIG. 8 as a single-well multi-parameter plot. The implementations may also generate a visualization for full well list focusing on each parameter, as further explained below with reference to each subpanel of FIG. 9, which is a multi-well, single parameter plot.

FIG. 8 shows an example of integrated visualization according to an implementation of the present disclosure. In FIG. 8, each subpanel shows, for a single well (well #1), liquid rate, oil rate, water injection rate, pressure, water-cut, gas-oil ratio, MDT, PLT, PNL, permeability, porosity, and perforation that match the simulation results. As illustrated in FIG. 8, the disclosed simulator platform generates an integrated visualization plot for a single well showing majority of historical data used for history-matching. The disclosed simulator platform can create and update the result plots as the simulation run progresses (e.g., multiple runs to iteratively improve/update the multiplication factor). None of conventional visualization tools allow such a comprehensive integration of a single-well results in a single visualization interface to provide a simultaneous multi-parameter plot for a single well. To create such unitized view of all parameters for a single well would take a substantial number of painstaking man-hours to create, even by an experienced engineer.

FIG. 9 shows an example of integrated visualization where all MDT pressure match the observed data in one view according to an implementation of the present disclosure. As illustrated in FIG. 9, an integrated visualization template can focus on a single parameter plot (e.g., MDT plot) for multiple wells. The visualization template can assemble all the well results into a single visualization. While some of today's visualization applications allow the experienced user to create templates, the templates may not be re-used in new projects that have different well names well-count and historical data dates. As such, user templates created for some of the conventional tools are only applicable to the cases for which the user templates have been created. If new wells are added to the list, a new template may need to be added. If a new project with different well names and well count is to be conducted, a new template may also need to be added. In addition, using the conventional visualization applications would require that the simulation result be first uploaded into the visualization application.

At the end of history matching, the disclosed simulator platform may carry out productivity index (PI) calibration to ensure that the well's performance under prediction are consistent with its historical performance. The process involves obtaining each well's PI from simulation output and comparing with historical measurement of PI. PI multiplier factors may then be imposed on each well to match its PI with observed data. In cases where the required PI multiplier is too low (e.g., <0.2) or too large (e.g., >5), a user may need to review the history-matched model's permeability in the vicinity of the applicable well(s). For studies with a large number of wells, such user review can be a cumbersome process that is time consuming.

For every well whose measured PI has been supplied as input, the disclosed simulator platform is encoded to obtain the simulated PI of the wells and calculate the necessary multiplier factor between the actual PI and the simulated PI. This factor is automatically written in the simulation file before launching the prediction run.

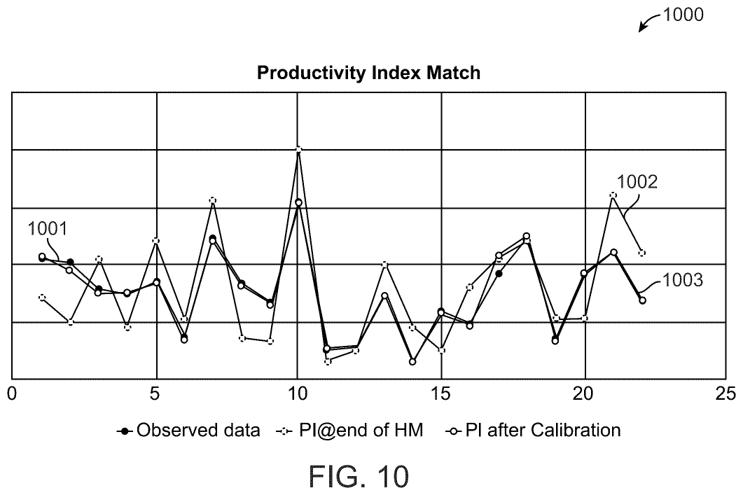

FIG. 10 shows an example of a production index (PI) calibration chart generated by platforms according to an implementation of the present disclosure. FIG. 10 shows an example output visualization generated by the disclosed simulator platform for 24 wells whose historical PIs were supplied as input. In graph 1000 of FIG. 1, the curve represented by dots 1001 shows the historical PIs for the wells, the curve represented by dots 1002 shows the corresponding simulation PIs of the wells at the corresponding observed data date for the history matched model. As can be seen, after history matching, the simulation PIs (represented by dots 1002) are somewhat showing mis-match with the observed well PI (represented by dots 1001). The mis-match ratio between the observed PIs and the simulation PIs can be used for PI calibration. The curve represented by dots 1003 shows the corresponding simulation PIs after the calibration exercise applying the mismatch ratio. As can be seen, the difference between the curve represented by dots 1003 (simulation with calibration) and the curve represented by dots 1001 (historical record) is smaller than the curve represented by dots 1002 (simulation without calibration) and the curve represented dots 1001 (historical record). Here, the simulator can automatically determine the correction ratio to match the results of the simulation to the corresponding records of historical PI. A common trend in all three curves is that tasks traditionally carried out by the engineer outside of numerical simulators are now integrated seamlessly as an integral part of the simulation process, thereby saving significant time and effort in the same manner as an AI generator tool.

As illustrated in FIG. 1, prediction module 120 may perform a variety of tasks including, for example, PI matching (as explained above), infill and sidetrack well placement, LTP sheeting reporting, and other forms of reporting. As illustrated in FIG. 2, the workflow on the disclosed simulator platform may handle automation of forecast related requirements such as sidetrack and infill wells, PI matching (arc 205). The workflow may additionally handle simulation run management by providing HM statistics, well-types and counts, STOOIP and recovery factor calculation (arc 206). The workflow may further handle automatic report generation including templates for internal and external reports (arc 207). The workflow may also handle live update of pressure and production data (arc 208), as the underlying data are being updated or refreshed.

During the prediction simulation run, a prediction scenario can occur in which only the wells existing at the end of history matching are used for the forecast. However, other prediction scenarios could include the identification of un-swept or bypassed areas where new infill wells may be drilled, or in some other cases, wells that are producing at high water-cut may be required to be side-tracked. Using traditional tools and processes, the tasks of infill and sidetrack well planning is done at the end of a no further activity (NFA) prediction. The NFA prediction is imported into a 3D visualization application to inspect potential areas of infill and sidetrack. Well planning is carried out in the external application, and the trajectory of the proposed infill and sidetrack wells are then imported into the simulator to conduct a new run.

The disclosed simulator platform can be programmed to search the entire simulation grid at intervals (e.g., annually or other time steps) and identify the best spots (e.g., meeting optimality criteria) to drill infill wells. The interval or frequency (measured in month or year) can be provided by a user input. Depending on the number of wells the user has requested, the simulator can use instantaneous cumulative production at the end of simulation to rank the wells that the simulator has automatically spotted, and retain the best required number of wells. For example, the disclosed simulator platform can automatically create the wells at these identified locations at simulation runtime. The disclosed simulator platform can also check the water-cut of every well at intervals (e.g., annually or other time steps). By way of illustration, for every well whose water-cut is above a user-defined trigger point, sweet-spot zones and direction are searched, and the new sidetrack well is automatically created to replace the original well.

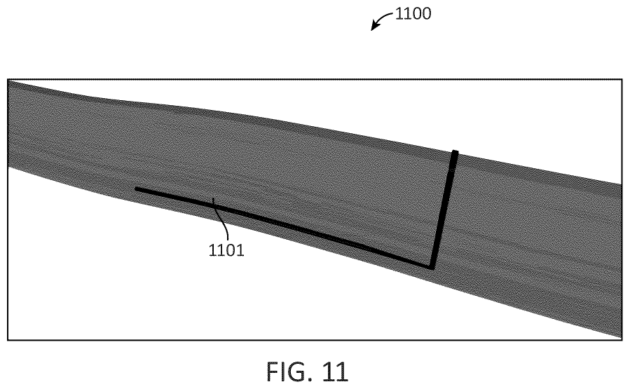

FIG. 11 shows a map 1100 illustrating an example of a sidetrack well drilled within an undrained zone of an existing production well, as guided by indications automatically created by a disclosed simulator platform during the course of a simulation run according to an implementation of the present disclosure. The sidetracks would have required significant manhours (e.g., several weeks of engineer's time) to perform.

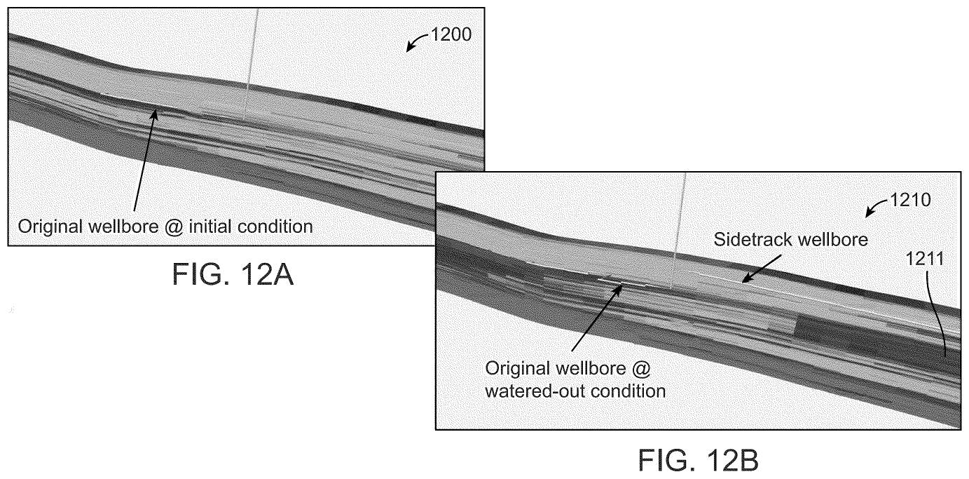

FIGS. 12A to 12B illustrate additional details of applying the sidetrack from FIG. 11 according to an implementation of the present disclosure. Specifically, FIGS. 12A and 12B provide a cross-section at the location of one of the wells indicating that the well's sidetrack has been place in an area with sufficient quality where an expert engineer would have manually placed the sidetrack. The cross-section refers to a directional slice through a 3-D model. FIG. 12A depicts view 1200 which contains only the original well. After producing the original well for some years, water begins to arrive at the well. FIG. 12B depicts view 1210 in which the a sidetrack well is drilled in the upper section of the original well where the oil has hot yet been invaded by water. As observed in FIG. 12A, the presence of oil is indicated all around the immediate location of the original well. However, in FIG. 12B, this area around the original well's lateral (annotated by arrow 1211) has changed, indicating arrival of water at the wellbore. Nonetheless, this change is not observed at the upper layers around the well FIG. 12B, that is the reason the platform automatically designs a sidetrack producer at this upper layer in order to produce oil with no associated water, while shutting off the original well which now produces oil with associated water.

At the end of a simulation run, graphic and textual output can be generated to complete formatted reports for submission to finance or economic evaluation teams internally or externally (e.g., security and exchange commission (SEC) disclosure). Traditionally, the engineer needs to load the simulation results into an external visualization application and obtain this information from various sections of the results file. Examples of such information include production and injection fluids and rate profiles, well type and count, pressure profile, reserve and hydrocarbon in-place (HCIP). This process could be time consuming and tedious as data has to be extracted from simulation and significant time would be incurred for data formatting and sometimes conversion into alternatives units required by the report templates.

The disclosed simulator platform can be program to mine all necessary information, for example, from different computing threads on simulation runs so that the data can be triaged and assembled in the format and units according to reporting standards. A formatted and finalized reporting can be saved for a user to submit, for example, to an external regulatory agency.

After completing a reservoir model, it usually takes at least the next 3 years until sufficient quantity of new geological information is available to re-build the static model. However, during this 3-years of maintaining the static model, field management operations generate frequent dynamic data such as production/injection rates, datum pressures, well-test PTA, MDT, and PNL information. It is therefore traditional practice to update an existing dynamic model with new dynamic data at intervals (for example, quarterly, or annually). During the update, the user may append new data to the existing dynamic model data and uses these new data to review or redo the history matching.

By way of example, let us assume a dynamic modelling project was completed in year t0. At the end of year t1 all the newly acquired dynamic data are appended to the dynamic data file at t0. The dynamic model at t0 is then run in prediction mode and its results are compared with the new data available at t1. If there is satisfactory match between the predicted results and the latest observed data, then the dynamic model is still robust enough for field operations planning. However, if there is large deviation between the prediction and the new available data, plans are made to update the static and dynamic model.

This live model update is a periodic activity that also takes time and effort. The disclosed simulator platform can be program to directly access the official repository/database where these data reside. For example, the implementations can periodically scan the file repository by using the data-stamp on the current dynamic data file to determine whether the data are more recent in the database, and if so, the implementations can extract the data to update the dynamic data file. Additionally, or alternatively, the implementations may incorporate a software trigger that once the data in the file repository has been updated, the underlying simulator is activated to reload the newly updated load for an updated simulation run. In this and other ways, a task that could take significant input from an engineer, can be completed in few seconds by implementations of the present disclosure.

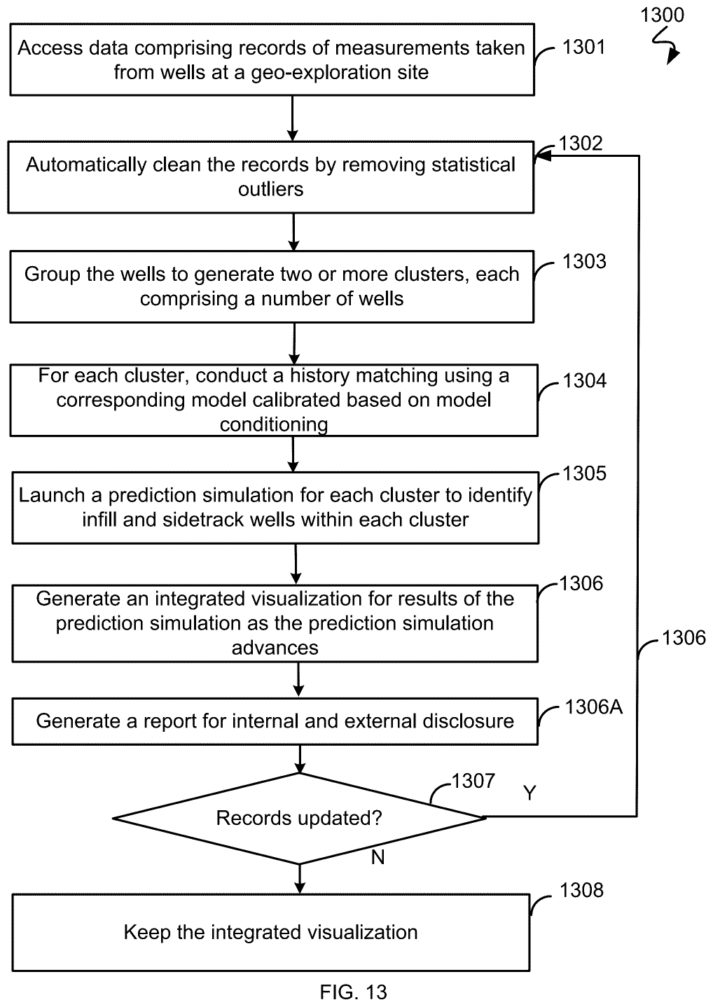

FIG. 13 shows an example of a flow chart 1300 according to an implementation of the present disclosure. The illustrated process may access data that include, for example, records of measurements taken from wells at a geo-exploration site (1001). The geo-exploration site is vast enough to contain, for example, hundreds or more wells where measurements have been taken to record geophysical parameters such as pressure, and rate. Each measurement may be associated with a time when the measurement is taken. The geo-exploration site may be modelled using a large size of grid-blocks, for example, hundreds of millions to several billions, as permitted by memory storage. The geo-exploration site may also be referred to as a reservoir, which has an associated reservoir model.

The illustrated process may automatically clean the records by removing statistical outliers (1302). As explained above in association with FIGS. 3A-3B, the statistical outliers represent non-physics-based data, which, if not cleaned, can lead to a misfit error in a physics-based flow simulator. In some implementations, a statistical outlier can refer to a data point with less than a threshold level of probability of occurrence (e.g., 10%).

The illustrated process may automatically group the wells into a number of clusters, each having a similar time-lapsed trend (1303). The similar time-lapsed trend may refer to a trend of pressure measurements. FIGS. 4, and 5A-5B provide examples of results of clustering in which the wells within each pressure cluster are enclosed inside a boundary 2D polygon. As explained above further in association with FIGS. 6A-6B, some implementations can perform clustering using pattern recognition, automatic creation of boundary polygons around identified well groups, and an automatic re-shaping algorithm that translates the 2D polygon into a 3D array containing a unique region number within each closed polygon. The clustering results can be exported to a flow-physics based simulator to provide regional permeability updates.

The illustrated process may then conduct, for each cluster, a history matching using a corresponding model (1304). In some implementations, the corresponding model may be calibrated using modeling conditioning. For example, kh-calibration may be performed using a multi-well full-field model approach to compute the permeability multiplier factor necessary to match each test-well's simulated derivative to its observed data derivative. Armed with the permeability correction factors for each tested-well, the illustrated process can automatically resume a new simulation run in which the calculated multiplier is incorporated within 1 km radius of the applicable wells.

The illustrated process may launch a prediction simulation for each cluster to identify infill and sidetrack wells within each cluster (1305). For example, the illustrated process may search the entire simulation grid at regular intervals (e.g., yearly) and identify the best spots (e.g., meeting optimality criteria) to drill infill wells. Here, for every well whose water-cut is above a user-defined trigger point, sweet-spot zones and direction are searched, and the new sidetrack well can be automatically created to replace the original well, as illustrated above in FIGS. 11-12.

The illustrated process may generate an integrated visualization for results of the prediction simulation as the prediction simulation advances (1306). As explained above in association with FIGS. 1-2, and 8-9, visualization template can assemble all the well results into a single visualization for the full complement of measurement types (e.g., production, production ratios, MDT, PLT, PNL, porosity, permeability and perforation), and carry out productivity index (PI) calibration to ensure that the well's performance under prediction are consistent with its historical performance. At the end of a simulation run, graphic and textual output can be generated to complete formatted reports for submission to finance or economic evaluation teams internally or externally (e.g., security and exchange commission (SEC) disclosure). This is specifically indicated in block 1306A.

The illustrated process may determine whether the underlying records from each well has been updated (1307). The update can refer to new measurements obtained from a well inside an identified cluster, a revised measurement to amend existing records. In response to determining the records has been updated, the illustrated process may continue to pre-process the updated record (1302). Specifically, the illustrated process accommodates dynamic modeling in which live update can be provided to relevant simulator tog generate, for example, an amended report, or a refreshed visualization plot. As explained above, the illustrated process can scan the file repository by using the data-stamp on the current dynamic data file to determine whether the data are more recent in the database, and if so, the illustrated process can extract the data to update the dynamic data file. Additionally, or alternatively, the illustrated process may incorporate a software trigger that once the data in the file repository has been updated, the underlying simulator is activated to reload the newly updated load for an updated simulation run. In response to determining the records has not been updated, the illustrated process may maintain the integrated visualization (1308),

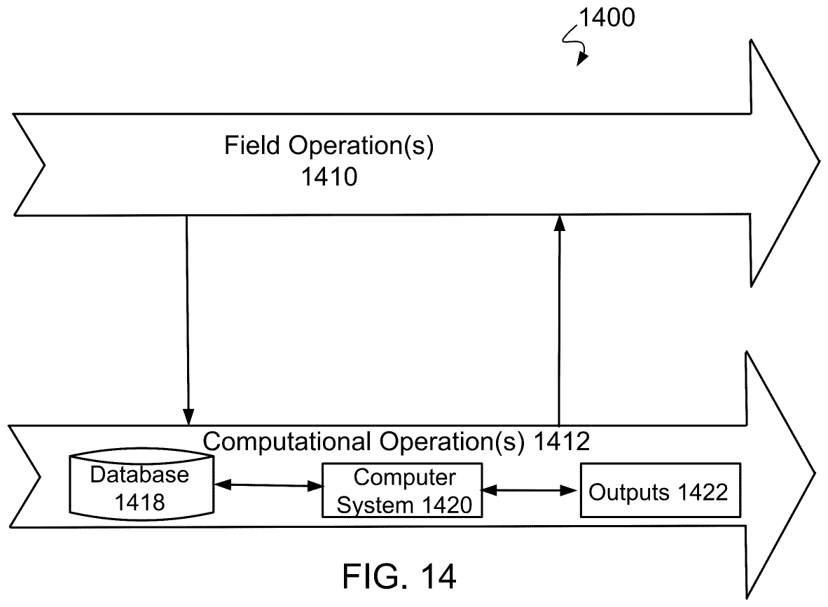

FIG. 14 is a block diagram illustrating an example of hydrocarbon production operations that include field operations and computational operations, according to an implementation of the present disclosure. Exploration and production operations 1400 include both one or more field operations 1410 and one or more computational operations 1412, which exchange information and control exploration for the exploration and production of hydrocarbons. In some implementations, outputs of techniques of the present disclosure can be performed before, during, or in combination with the hydrocarbon exploration and production operations 1400, specifically, for example, either as field operations 1410 or computational operations 1412, or both.

Examples of field operations 1410 include surveying operations, forming/drilling a wellbore, hydraulic fracturing, producing through the wellbore, injecting fluids (such as water) through the wellbore, to name a few. In some implementations, methods of the present disclosure can trigger or control the field operations 1410. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 1410 and responsively triggering the field operations 1410 including, for example, generating plans and signals that provide feedback to and control physical components of the field operations 1410. Alternatively or in addition, the field operations 1410 can trigger the methods of the present disclosure. For example, implementing physical components (including, for example, hardware, such as sensors) deployed in the field operations 1410 can generate plans and signals that can be provided as input or feedback (or both) to the methods of the present disclosure.

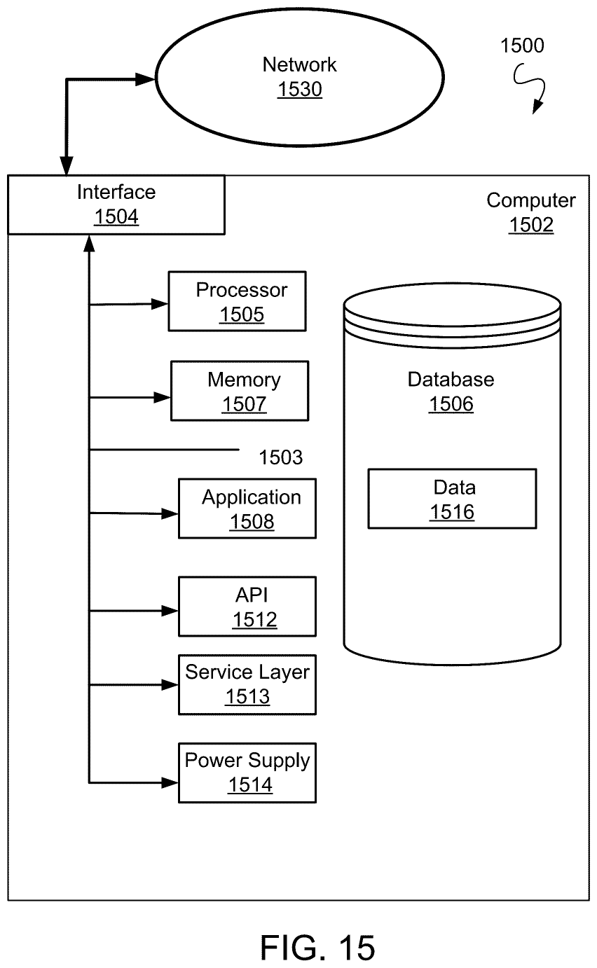

Examples of computational operations 1412 include one or more computer systems 1420 that include one or more processors and computer-readable media (e.g., non-transitory computer-readable media) operatively coupled to the one or more processors to execute computer operations to perform the methods of the present disclosure. A more detailed example can be found in FIG. 15. The computational operations 1412 can be implemented using one or more databases 1418, which store data received from the field operations 1410 and/or generated internally within the computational operations 1412 (e.g., by implementing the methods of the present disclosure) or both. For example, the one or more computer systems 1420 process inputs from the field operations 1410 to assess conditions in the physical world, the outputs of which are stored in the databases 1418. For example, seismic sensors of the field operations 1410 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 1412 where they are stored in the databases 1418 and analyzed by the one or more computer systems 1420.

In some implementations, one or more outputs 1422 generated by the one or more computer systems 1420 can be provided as feedback/input to the field operations 1410 (either as direct input or stored in the databases 1418). The field operations 1410 can use the feedback/input to control physical components used to perform the field operations 1410 in the real world.

For example, the computational operations 1412 can process the seismic data to generate three-dimensional (3D) maps of the subsurface formation. The computational operations 1412 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 1412 to process new information about the formation and control the drilling to adjust to the observed conditions in real-time.

The one or more computer systems 1420 can update the 3D maps of the subsurface formation as information from one exploration well is received and the computational operations 1412 can adjust the location of the next exploration well based on the updated 3D maps. Similarly, the data received from production operations can be used by the computational operations 1412 to control components of the production operations. For example, production well and pipeline data can be analyzed to predict slugging in pipelines leading to a refinery and the computational operations 1412 can control machine operated valves upstream of the refinery to reduce the likelihood of plant disruptions that run the risk of taking the plant offline.

In some implementations of the computational operations 1412, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

FIG. 15 is a block diagram illustrating an example of a computer system 1500 used to provide computational functionalities associated with described algorithms, methods, functions, processes, flows, and procedures, according to an implementation of the present disclosure. The illustrated computer 1502 is intended to encompass any computing device such as a server, desktop computer, laptop/notebook computer, wireless data port, smart phone, personal data assistant (PDA), tablet computing device, one or more processors within these devices, another computing device, or a combination of computing devices, including physical or virtual instances of the computing device, or a combination of physical or virtual instances of the computing device. Additionally, the computer 1502 can comprise a computing device that includes an input device, such as a keypad, keyboard, touch screen, another input device, or a combination of input devices that can accept user information, and an output device that conveys information associated with the operation of the computer 1502, including digital data, visual, audio, another type of information, or a combination of types of information, on a graphical-type user interface (UI) (or GUI) or other UI.

The computer 1502 can serve in a role in a computer system as a client, network component, a server, a database or another persistency, another role, or a combination of roles for performing the subject matter described in the present disclosure. The illustrated computer 1502 is communicably coupled with a network 1530. In some implementations, one or more components of the computer 1502 can be configured to operate within an environment, including cloud-computing-based, local, global, another environment, or a combination of environments.

The computer 1502 is an electronic computing device operable to receive, transmit, process, store, or manage data and information associated with the described subject matter. According to some implementations, the computer 1502 can also include or be communicably coupled with a server, including an application server, e-mail server, web server, caching server, streaming data server, another server, or a combination of servers.

The computer 1502 can receive requests over network 1530 (for example, from a client software application executing on another computer 1502) and respond to the received requests by processing the received requests using a software application or a combination of software applications. In addition, requests can also be sent to the computer 1502 from internal users, external or third-parties, or other entities, individuals, systems, or computers.

Each of the components of the computer 1502 can communicate using a system bus 1503. In some implementations, any or all of the components of the computer 1502, including hardware, software, or a combination of hardware and software, can interface over the system bus 1503 using an application programming interface (API) 1512, a service layer 1513, or a combination of the API 1512 and service layer 1513. The API 1512 can include specifications for routines, data structures, and object classes. The API 1512 can be either computer-language independent or dependent and refer to a complete interface, a single function, or even a set of APIs. The service layer 1513 provides software services to the computer 1502 or other components (whether illustrated or not) that are communicably coupled to the computer 1502. The functionality of the computer 1502 can be accessible for all service consumers using this service layer. Software services, such as those provided by the service layer 1513, provide reusable, defined functionalities through a defined interface. For example, the interface can be software written in JAVA, C++, another computing language, or a combination of computing languages providing data in extensible markup language (XML) format, another format, or a combination of formats. While illustrated as an integrated component of the computer 1502, alternative implementations can illustrate the API 1512 or the service layer 1513 as stand-alone components in relation to other components of the computer 1502 or other components (whether illustrated or not) that are communicably coupled to the computer 1502. Moreover, any or all parts of the API 1512 or the service layer 1513 can be implemented as a child or a sub-module of another software module, enterprise application, or hardware module without departing from the scope of the present disclosure.

The computer 1502 includes an interface 1504. Although illustrated as a single interface 1504 in FIG. 15, two or more interfaces 1504 can be used according to particular needs, desires, or particular implementations of the computer 1502. The interface 1504 is used by the computer 1502 for communicating with another computing system (whether illustrated or not) that is communicatively linked to the network 1530 in a distributed environment. Generally, the interface 1504 is operable to communicate with the network 1530 and comprises logic encoded in software, hardware, or a combination of software and hardware. More specifically, the interface 1504 can comprise software supporting one or more communication protocols associated with communications such that the network 1530 or interface's hardware is operable to communicate physical signals within and outside of the illustrated computer 1502.

The computer 1502 includes a processor 1505. Although illustrated as a single processor 1505 in FIG. 15, two or more processors can be used according to particular needs, desires, or particular implementations of the computer 1502. Generally, the processor 1505 executes instructions and manipulates data to perform the operations of the computer 1502 and any algorithms, methods, functions, processes, flows, and procedures as described in the present disclosure.

The computer 1502 also includes a database 1506 that can hold data for the computer 1502, another component communicatively linked to the network 1530 (whether illustrated or not), or a combination of the computer 1502 and another component. For example, database 1506 can be an in-memory, conventional, or another type of database storing data consistent with the present disclosure. In some implementations, database 1506 can be a combination of two or more different database types (for example, a hybrid in-memory and conventional database) according to particular needs, desires, or particular implementations of the computer 1502 and the described functionality. Although illustrated as a single database 1506 in FIG. 15, two or more databases of similar or differing types can be used according to particular needs, desires, or particular implementations of the computer 1502 and the described functionality. While database 1506 is illustrated as an integral component of the computer 1502, in alternative implementations, database 1506 can be external to the computer 1502. As illustrated, the database 1506 holds data 1516 including, for example, well test data from all wells in the reservoir, as explained in more detail in association with FIGS. 1-12.

The computer 1502 also includes a memory 1507 that can hold data for the computer 1502, another component or components communicatively linked to the network 1530 (whether illustrated or not), or a combination of the computer 1502 and another component. Memory 1507 can store any data consistent with the present disclosure. In some implementations, memory 1507 can be a combination of two or more different types of memory (for example, a combination of semiconductor and magnetic storage) according to particular needs, desires, or particular implementations of the computer 1502 and the described functionality. Although illustrated as a single memory 1507 in FIG. 15, two or more memories 1507 or similar or differing types can be used according to particular needs, desires, or particular implementations of the computer 1502 and the described functionality. While memory 1507 is illustrated as an integral component of the computer 1502, in alternative implementations, memory 1507 can be external to the computer 1502.

The application 1508 is an algorithmic software engine providing functionality according to particular needs, desires, or particular implementations of the computer 1502, particularly with respect to functionality described in the present disclosure. For example, application 1508 can serve as one or more components, modules, or applications. Further, although illustrated as a single application 1508, the application 1508 can be implemented as multiple applications 1508 on the computer 1502. In addition, although illustrated as integral to the computer 1502, in alternative implementations, the application 1508 can be external to the computer 1502.

The computer 1502 can also include a power supply 1514. The power supply 1514 can include a rechargeable or non-rechargeable battery that can be configured to be either user- or non-user-replaceable. In some implementations, the power supply 1514 can include power-conversion or management circuits (including recharging, standby, or another power management functionality). In some implementations, the power-supply 1514 can include a power plug to allow the computer 1502 to be plugged into a wall socket or another power source to, for example, power the computer 1502 or recharge a rechargeable battery.

There can be any number of computers 1502 associated with, or external to, a computer system containing computer 1502, each computer 1502 communicating over network 1530. Further, the term “client,” “user,” or other appropriate terminology can be used interchangeably, as appropriate, without departing from the scope of the present disclosure. Moreover, the present disclosure contemplates that many users can use one computer 1502, or that one user can use multiple computers 1502.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal, for example, a machine-generated electrical, optical, or electromagnetic signal that is generated to encode information for transmission to a receiver apparatus for execution by a data processing apparatus. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” or “electronic computer device” (or equivalent as understood by one of ordinary skill in the art) refer to data processing hardware and encompass all kinds of apparatus, devices, and machines for processing data, including by way of example, a programmable processor, a computer, or multiple processors or computers. The apparatus can also be, or further include special purpose logic circuitry, for example, a central processing unit (CPU), an FPGA (field programmable gate array), or an ASIC (application-specific integrated circuit). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with an operating system of some type, for example LINUX, UNIX, WINDOWS, MAC OS, ANDROID, IOS, another operating system, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and apparatus can also be implemented as, special purpose logic circuitry, for example, a CPU, an FPGA, or an ASIC.

Computers for the execution of a computer program can be based on general or special purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device.

Non-transitory computer-readable media for storing computer program instructions and data can include all forms of media and memory devices, magnetic devices, magneto optical disks, and optical memory device. Memory devices include semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Magnetic devices include, for example, tape, cartridges, cassettes, internal/removable disks. Optical memory devices include, for example, digital video disc (DVD), CD-ROM, DVD+/−R, DVD-RAM, DVD-ROM, HD-DVD, and BLURAY, and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special purpose logic circuitry.

To provide for interaction with a user, implementations of the subject matter described in this specification can be implemented on a computer having a display device, for example, a CRT (cathode ray tube), LCD (liquid crystal display), LED (Light Emitting Diode), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity, a multi-touch screen using capacitive or electric sensing, or another type of touchscreen. Other types of devices can be used to interact with the user. For example, feedback provided to the user can be any form of sensory feedback. Input from the user can be received in any form, including acoustic, speech, or tactile input. In addition, a computer can interact with the user by sending documents to and receiving documents from a client computing device that is used by the user.

The term “graphical user interface,” or “GUI,” can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11 a/b/g/n or 802.20 (or a combination of 802.11x and 802.20 or other protocols consistent with the present disclosure), all or a portion of the Internet, another communication network, or a combination of communication networks. The communication network can communicate with, for example, Internet Protocol (IP) packets, Frame Relay frames, Asynchronous Transfer Mode (ATM) cells, voice, video, data, or other information between networks addresses.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

What is claimed is:

1. A computer-implemented method comprising:
accessing data comprising records of measurements obtained from a plurality of wells of a reservoir over a period of time;
automatically removing statistical outliers from the records to generate clean records, wherein the statistical outliers represent a probability of occurring in the records that is below a threshold;
automatically grouping, based on the clean records, the plurality of wells into a set of clusters, each cluster comprising one or more wells whose corresponding records exhibit a shared trend over at least a portion of the period of time;
conducting, for each cluster, a history matching simulation using a corresponding model, wherein the corresponding model is calibrated;
launching, based on results of the history matching simulation, a prediction simulation to automatically identify at least one of an infill well and a sidetrack well within each cluster; and
generating an integrated visualization for results of the prediction simulation as the prediction simulation advances.

2. The computer-implemented method of claim 1, further comprising:
in response to determining that the records have been updated, dynamically updating the integrated visualization by re-launching the prediction simulation based on the history matching simulation using the records that have been updated.

3. The computer-implemented method of claim 2, wherein determining that the records have been updated comprises:
scanning a database storing the records to determine whether at least one record has a time stamp that is more recent than indicated in a previous scan of the database.

4. The computer-implemented method of claim 1, wherein the corresponding model is calibrated using a permeability (kh)-calibration based on a multi-well full-field model to compute a permeability multiplier factor to match each well's simulated derivative to a corresponding observed derivative.

5. The computer-implemented method of claim 4, further comprising:
re-launching the history matching simulation in which the permeability multiplier factor is incorporated within a radius of the each well whose simulated derivative has been matched to the corresponding observed derivative.

6. The computer-implemented method of claim 1, further comprising:
planning a location of a new well in the reservoir as indicated by the at least one of an infill well and a sidetrack well.

7. The computer-implemented method of claim 6, wherein the prediction simulation identifies the at least one of an infill well and a sidetrack well by searching a full simulation grid for each cluster along multiple directions of the full simulation grid.

8. The computer-implemented method of claim 1, wherein the integrated visualization comprises a computer-generated report that assembles results from the prediction simulation.

9. The computer-implemented method of claim 1, wherein the integrated visualization comprises plots for productivity index (PI) for each well.

10. A computer system comprising one or more computer processors configured to perform operations of:
accessing data comprising records of measurements obtained from a plurality of wells of a reservoir over a period of time;
automatically removing statistical outliers from the records to generate clean records, wherein the statistical outliers represent a probability of occurring in the records that is below a threshold;
automatically grouping, based on the clean records, the plurality of wells into a set of clusters, each cluster comprising one or more wells whose corresponding records exhibit a shared trend over at least a portion of the period of time;
conducting, for each cluster, a history matching simulation using a corresponding model, wherein the corresponding model is calibrated;
launching, based on results of the history matching simulation, a prediction simulation to automatically identify at least one of an infill well and a sidetrack well within each cluster; and
generating an integrated visualization for results of the prediction simulation as the prediction simulation advances.

11. The computer system of claim 10, wherein the operations further comprise:
in response to determining that the records have been updated, dynamically updating the integrated visualization by re-launching the prediction simulation based on the history matching simulation using the records that have been updated.

12. The computer system of claim 11, wherein determining that the records have been updated comprises:
scanning a database storing the records to determine whether at least one record has a time stamp that is more recent than indicated in a previous scan of the database.

13. The computer system of claim 10, wherein the corresponding model is calibrated using a permeability (kh)-calibration based on a multi-well full-field model to compute a permeability multiplier factor to match each well's simulated derivative to a corresponding observed derivative.

14. The computer system of claim 13, wherein the operations further comprise:
re-launching the history matching simulation in which the permeability multiplier factor is incorporated within a radius of the each well whose simulated derivative has been matched to the corresponding observed derivative.

15. The computer system of claim 10, wherein the operations further comprise:
planning a location of a new well in the reservoir as indicated by the at least one of an infill well and a sidetrack well.

16. The computer system of claim 15, wherein the prediction simulation identifies the at least one of an infill well and a sidetrack well by searching a full simulation grid for each cluster along multiple directions of the full simulation grid.

17. The computer system of claim 10, wherein the integrated visualization comprises a computer-generated report that assembles results from the prediction simulation.

18. The computer system of claim 10, wherein the integrated visualization comprises plots for productivity index (PI) for each well.

19. One or more computer storage devices comprising software instructions which, when executed by one or more computer processors, cause the one or more computer processors to perform operations of:
accessing data comprising records of measurements obtained from a plurality of wells of a reservoir over a period of time;
automatically removing statistical outliers from the records to generate clean records, wherein the statistical outliers represent a probability of occurring in the records that is below a threshold;
automatically grouping, based on the clean records, the plurality of wells into a set of clusters, each cluster comprising one or more wells whose corresponding records exhibit a shared trend over at least a portion of the period of time;
conducting, for each cluster, a history matching simulation using a corresponding model, wherein the corresponding model is calibrated;
launching, based on results of the history matching simulation, a prediction simulation to automatically identify at least one of an infill well and a sidetrack well within each cluster, and
generating an integrated visualization for results of the prediction simulation as the prediction simulation advances.

20. The one or more computer storage devices of claim 19, wherein the operations further comprise:
in response to determining that the records have been updated, dynamically updating the integrated visualization by re-launching the prediction simulation based on the history matching simulation using the records that have been updated.
